(19) United States
(12) Patent Application Publication
(10) Pub. No.: US 2024/0032274 A1
(43) Pub. Date: Jan. 25, 2024

(54) BACK-END-OF-LINE MEMORY DEVICES AND METHODS OF FABRICATING THE SAME

(71) Applicant: Taiwan Semiconductor Manufacturing Company, Ltd., Hsinchu (TW)

(72) Inventors: Peng-Chun Liou, Hsinchu (TW); Chia-En Huang, Hsinchu (TW); Ya-Yun Cheng, Hsinchu (TW); Chung-Wei Wu, Hsinchu (TW)

(73) Assignee: Taiwan Semiconductor Manufacturing Company, Ltd., Hsinchu (TW)

(21) Appl. No.: 18/103,377

(22) Filed: Jan. 30, 2023

Related U.S. Application Data
(60) Provisional application No. 63/390,349, filed on Jul. 19, 2022.

(51) Int. Cl. H10B 12/00

(52) U.S. Cl. CPC H10B 12/315; H10B 12/482; H10B 12/033; H10B 12/05

(57) ABSTRACT

A memory device includes a semiconductor substrate. The memory device includes a stack of channel layers over the semiconductor substrate, each channel layer including an oxide material. The memory device includes a word line structure interleaved with the stack of channel layers. The memory device includes a source feature and a drain feature on both sides of the stack of channel layers.

### CROSS-REFERENCE TO RELATED APPLICATIONS

The present application claims priority to U.S. Provisional Application No. 63/390,349, filed Jul. 19, 2022, and tilted “Back-End-Of-Line Memory Devices and Methods of Fabricating the Same,” the entire disclosure of which is incorporated herein by reference.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example memory device, in accordance with some embodiments.

FIG. 2 illustrates a perspective view revealing a cross-section along line AA′ of a portion of the example memory device as shown in FIG. 1, in accordance with some embodiments.

FIG. 3 illustrates a planar top view of a portion of the example memory device as shown in FIG. 1, in accordance with some embodiments.

FIG. 4 illustrates a cross-sectional view along line BB′ of a portion of the example memory device as shown in FIG. 1, in accordance with some embodiments.

FIG. 5 illustrates an example waveform associated with operating the example memory device as shown in FIG. 4, in accordance with some embodiments.

FIGS. 6, 7, 8, 9, 10, 11, 12, and 13 each illustrate a cross-sectional view along line BB′ of a portion of the example memory device as shown in FIG. 1, in accordance with some embodiments.

FIG. 14 is an example flow chart of a method for fabricating an example memory device, in accordance with some embodiments.

FIGS. 15A, 16A, 17A, 20A, 21A, 22A, 23A, 24A, and 25A illustrate perspective views of an example memory device during various fabrication stages of the method as shown in FIG. 14, in accordance with some embodiments.

FIGS. 15B, 16B, 17B, 20B, 21B, 22B, 23B, 24B, and 25B illustrate cross-sectional views along line BB′ of the example memory device as shown in FIGS. 15A, 16A, 17A, 20A, 21A, 22A, 23A, 24A, and 25A, respectively, during various fabrication stages of the method illustrated in FIG. 14, in accordance with some embodiments.

FIGS. 18 and 19 each illustrate a cross-sectional view along line BB′ of the example memory device as shown in FIGS. 16A and 17A, respectively, during various fabrication stages of the method illustrated in FIG. 14, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally directed to back-end-of-line (BEOL) memory devices and methods of fabricating the same. Specifically, the present disclosure is directed to BEOL memory devices having a three-dimensional (3D) channel structure including stacked nanosheets. While existing BEOL memory devices have been generally adequate, they have not been entirely satisfactory in all aspects. For example, planar channel structures of existing BEOL memory devices typically extend continuously between adjacent cells to avoid processing concerns. However, such configuration may lead to high current leakage between neighboring cells due to potential differences between source and drain even when the gate is turned off. Additionally, insufficient Ion (on-current) may be evident in BEOL memory devices with a planar channel structure due to small effective channel width. Therefore, for at least these reasons, improvements in BEOL memory devices may be desired.

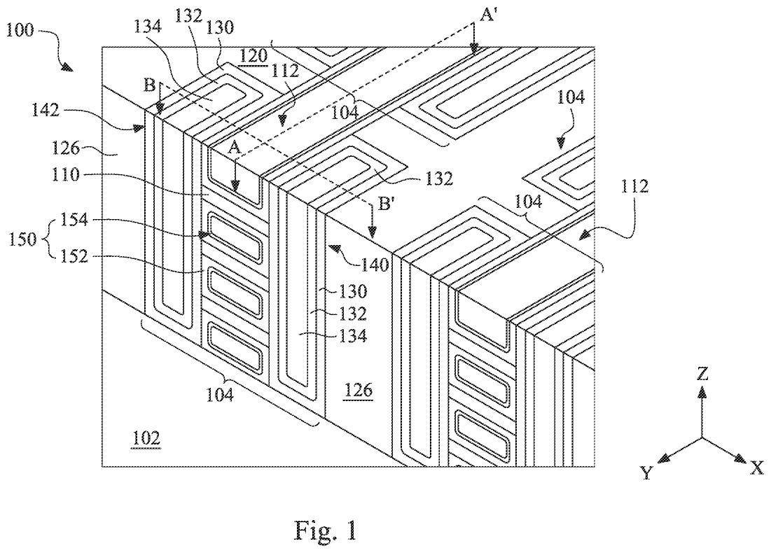

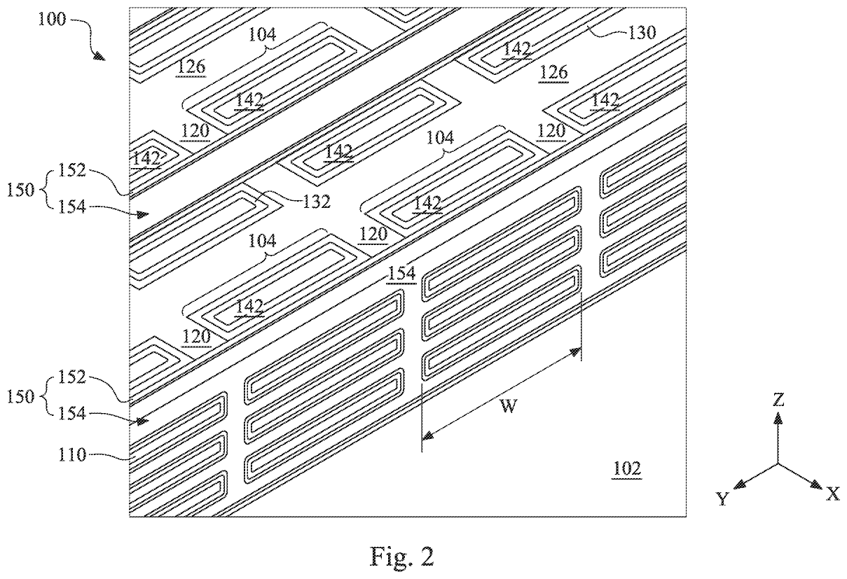

FIGS. 1 and 2 each illustrate a three-dimensional perspective view of a memory device 100, according to various embodiments of the present disclosure. It should be understood that the perspective view of FIGS. 1 and 2 are simplified, and thus, it should be understood that any other features/components can also be included in FIGS. 1 and 2, while remaining within the scope of the present disclosure.

As shown, the memory device 100 includes a number of memory cells 104 arranged as a memory array (e.g., four memory cells 104 are shown in the example of FIG. 1) that extends along both the X direction and the Y direction. It should be appreciated that, in some embodiments, any number of such memory layers may be stacked on top of one another (e.g., along the Z direction) to form the memory array. Each of the memory cells 104 can include a stack of interleaving WL structure and channel layers, where the WL structure functions as a gate to control the channel layers, and the channel layers are in electrical contact with a pair of source feature and drain feature, the details of which are discussed below.

In the present embodiments, the memory cell 104 includes a WL structure 150 over a semiconductor substrate 102, wherein the WL structure 150 extends continuously along the Y direction (e.g., two WL structures 150 are shown in the example of FIGS. 1 and 2) and is separated from an adjacent WL structure 150 along the X direction. The memory cell 104 further includes a plurality of channel layers 110 electrically coupled to the WL structure 150, where the channel layers 110 are interleaved with the WL structure 150 to form a stack 112 oriented along the Z direction. As shown in FIG. 2, the WL structure 150 wraps around each channel layer 110 within each memory cell 104, i.e., the channel layer 110 is discontinuous between adjacent or neighboring memory cells 104 along the Y direction. For at least this reason, the memory device 100 is referred to as a gate-all-around (GAA) device. Alternatively, as the channel layers 110 may be considered nanosheets (or nanorods), the memory device 100 may also be referred to as a nanosheet (NS) device. Advantageously, the wrapped-around structure allows the WL structure 150 to provide enhanced gate control over the channel layers 110, thereby mitigating potential leakage issues typically associated with planar memory devices for BEOL applications.

The semiconductor substrate 102 may include an elementary semiconductor material such as silicon, germanium, diamond, other elementary semiconductor material, a compound semiconductor material such as silicon germanium, silicon carbide, gallium arsenic, indium arsenide, indium phosphide, silicon germanium carbide, gallium arsenic phosphide, gallium indium phosphide, other compound semiconductor materials, or combinations thereof. A number of active/passive device features that collectively or respectively function as a logic circuit (e.g., transistors, capacitors, resistors, etc.) may be formed along a major surface of the semiconductor substrate 102.

One or more intermetal (IMD) layers may be embedded with a number of interconnect structures (e.g., conductive lines, vias) to electrically connect them to device features formed over the semiconductor substrate 102. Such device features formed along the major surface of the semiconductor substrate 102 are typically referred to as part of FEOL networking/processing, and those interconnect structures formed over the device features in the IMD layers are typically referred to as part of BEOL networking/processing. In various embodiments, the memory device 100, as disclosed herein, is formed within the BEOL networking. GAA devices including a semiconductor (e.g., Si-containing) channel may be formed as a part of the FEOL networking along the major surface of the semiconductor substrate 102 and electrically coupled to the memory device 100 through various interconnect structures.

Still referring to FIGS. 1 and 2, the WL structure 150 includes a conductive electrode (e.g., a gate electrode) 154 over a dielectric layer (e.g., a gate dielectric layer) 152. The dielectric layer 152 may include a metal oxide material, such as hafnium oxide (HfO₂), silicon oxide (SiO₂), aluminum oxide (Al₂O₃), silicon oxynitride (SiON), lanthanum oxide (La₂O₃), zirconium oxide (ZrO), other suitable dielectric materials, or combinations thereof. The conductive electrode 154 may include a conductive material, such as copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), golden (Au), aluminum (Al), TaN, TiN, TiAl, polysilicon, other suitable conductive materials, or combinations thereof. The conductive electrode 154 may include multiple layers, such as a metal fill layer over a barrier layer (and/or an adhesion layer).

A number of channel layers 110 included in each stack 112 (i.e., engaged with the WL structure 150) is not limited in the present embodiments and may be three, four, five, or other suitable numbers. In some embodiments, the number of channel layers 110 is adjusted to provide various benefits for the performance of the memory device 100. For example, referring to FIG. 2, a channel width W of each channel layer 110 is measured along the Y direction (e.g., the lengthwise direction of the channel layer 110) within each memory cell 104. As a result, an effective channel width W′ of each memory cell 104 takes into account the channel width W and the number of channel layers 110 included in each memory cell 104, or W′ n*W, where n is the number of channel layers 110. In this regard, a GAA memory device 100 including three channel layers 110 in each memory cell 104 has a W′ that is about three times (— 3W) that of its planar counterpart, which includes one channel layer only. Analogously, four channel layers 110 would provide an effective channel width W′ that is a four-time multiplication of W (— 4W), and so forth. An increase in W′ may improve the Ion (on-current) of the memory device 100, and in turn, enhance a selector charging speed of the device for high-speed applications.

Different from a front-end-of-line (FEOL) GAA devices, the channel layers 110 of the memory device 100, which is a BEOL memory device, are generally configured with one or more metal oxide-based semiconductor material. For example, in some embodiments, each channel layer 110 may be configured as an N-type channel layer that includes indium gallium zinc oxide (IGZO), zinc oxide (ZnO), indium oxide (In₂O₃), tin oxide (SnO₂), other suitable N-type metal oxide materials, or combinations thereof. In some embodiments, the channel layer 110 may be configured as a P-type channel layer that includes nickel oxide (NiO), copper oxide (Cu₂O), copper aluminum oxide (CuAlO₂), copper gallium oxide (CuGaO₂), copper indium oxide (CuInO₂), strontium copper oxide (SrCu₂O₂), tin oxide (SnO), other suitable P-type metal oxide materials, or combinations thereof. Other metal oxide materials, such as indium tungsten oxide (IWO), indium zinc oxide (IZO), indium tungsten zin oxide (IWZO), indium tin zinc oxide (ITZO), indium tin oxide (ITO), and/or indium gallium oxide (IGO) may also be included in the channel layers 110. In some embodiments, the concentration of oxygen in the channel layer 110 may be adjusted to achieve specific design requirements. In the present embodiments, the channel layer 110 is free, or substantially free, of any silicon-containing semiconductor material.

The memory cell 104 further includes a pair of drain feature 140 and source feature 142 (alternatively and collectively referred to as S/D features) disposed on each side of the WL structure 150 such that the channel layer 110 is interposed between the pair of S/D features. In the present disclosure, the source feature 142 may be alternatively referred to as a source metal electrode and the drain feature 140 may be alternative referred to as a drain metal electrode. As shown, the channel layer 110, which is coupled to the WL structure 150, is in contact with a corresponding pair of the drain feature 140 and the source feature 142.

In the present embodiments, the drain feature 140 and the source feature 142 include the same composition and may include multiple material layers. For example, still referring to FIGS. 1 and 2, each of the drain feature 140 and the source feature 142 includes a contact layer 130, a metal layer 132 over the contact layer 130, and a metal layer 134 over the metal layer 132.

In the present embodiments, the contact layer 130 includes a material similar to that of channel layer 110 as discussed in detail above. For example, the contact layer 130 may include an N-type metal oxide material, a P-type metal oxide material, other suitable materials, or combinations thereof. In some embodiments, the contact layer 130 includes the same type metal oxide material as that of the channel layer 110. In further embodiments, the concentration of oxygen in each of the drain feature 140 and the source feature 142 is less than that of the channel layer 110. For example, the concentration of oxygen of the channel layer 110 may be about 10¹⁸ cm⁻³ to about 10²⁰ cm⁻³, and the concentration of oxygen of each of the drain feature 140 and the source feature 142 may be about 10¹⁵ cm⁻³ to about 10¹⁷ cm⁻³. In some embodiments, the contact layer 130 is configured to lower the contact resistance between the channel layer 110 and each of the drain feature 140 and the source feature 142. In some embodiments, the contact layer 130 is configured to prevent hydrogen generated by subsequent device fabrication process to enter the channel layer 110.

In the present embodiments, the metal layers 132 and 134 each include a conductive material, such as TaN, TiN, W, Al, polysilicon, Ru, Co, Cu, Mo, Nb, other suitable conductive materials, or combinations thereof, and the metal layers 132 and 134 differ in composition. In some embodiments, the metal layer 134 includes a conductive material having a lower contact resistance that that of the metal layer 132. For example, in the depicted embodiments, the metal layer 132 includes TiN and the metal layer 134 includes W. In some instances, the metal layer 132 may be considered a barrier layer and the metal layer 134 may be considered a metal fill layer. In some embodiments, compositions of the metal layers 132 and 134 differ from that of the conductive electrode 154.

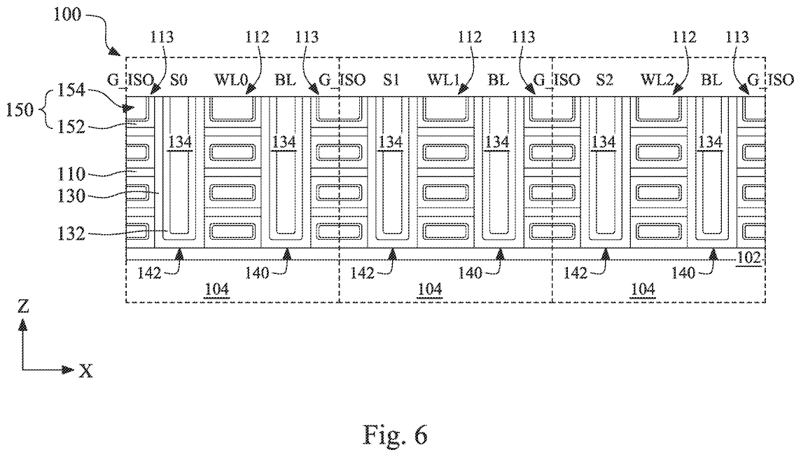

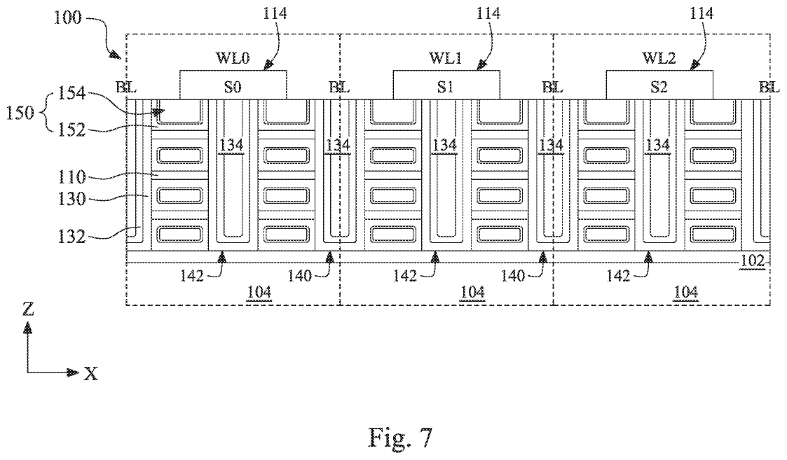

In some embodiments, as depicted in FIGS. 1 and 2, adjacent memory cells 104 are laterally separated by a dielectric layer. For example, along the Y direction, adjacent memory cells 104 are separated by dielectric layer 120, and along the X direction, adjacent memory cells 104 are separated by dielectric layer 126, which may be similar to the dielectric layer 120 in composition. The dielectric layers 120 and 126 may each include silicon oxide (SiO), silicon nitride (SiN), silicon oxynitride (SiON), dielectric material(s) with low dielectric constant (low-k) such as SiCOH, SiOCN, and/or SiOC, other suitable materials, or combinations thereof. A low-k dielectric material is a dielectric material with a dielectric constant lower than about 3.9. In some embodiments, as depicted in FIGS. 6 and 7, for example, adjacent memory cells 104 are separated by the stacks 112, rather than by the dielectric layer 126, along the X direction.

Each memory cell 104 of the memory device 100 may be defined as a combination of the WL structure 150, a plurality of channel layers 110 interleaved with the WL structure 150 in the stack 112, and one pair of the drain feature 140 and the source feature 142 engaged with the channel layers 110. Such a memory cell 104 may be implemented as a transistor structure (sometimes referred to as a “one-transistor (1T) structure”) with a gate, a gate oxide/dielectric layer, a semiconductor channel, a source, and a drain. The WL structure 150, the plurality of channel layers 110, the drain feature 140, and the source feature 142 may function as a gate, a semiconductor channel, a drain, and a source of the memory cell 104, respectively.

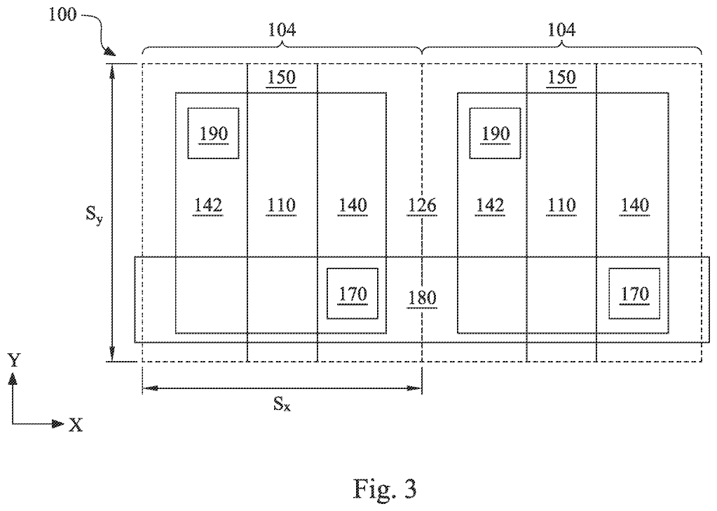

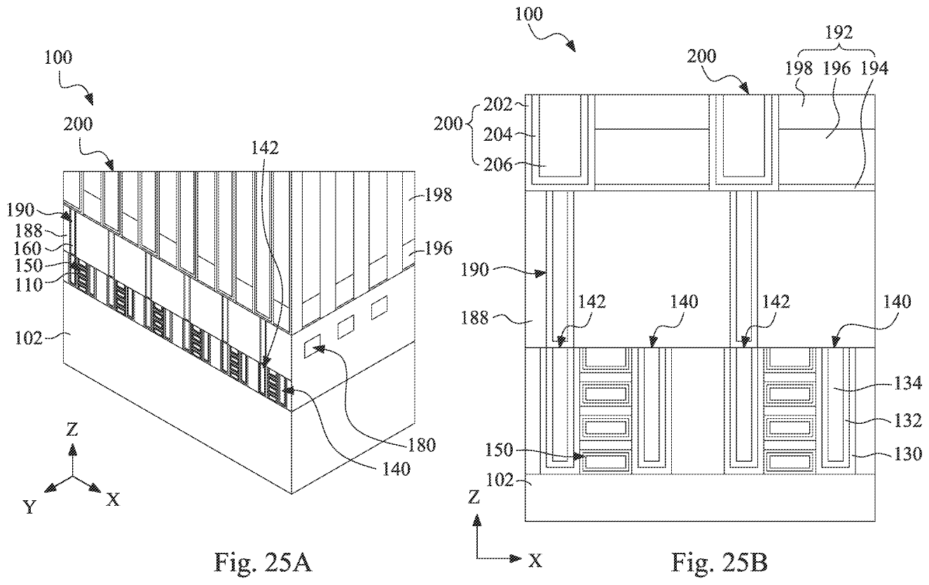

FIG. 3 depicts a top view of a portion of the memory device 100 as shown in FIGS. 1 and 2 that includes two memory cells 104 disposed adjacent to one another. Each memory cell 104 is defined by a cell width SX along the X direction and a cell height Sy along the Y direction. In some embodiments, the cell width SX may vary depending upon design requirements. As shown in each memory cell 104, the drain feature 140 is electrically coupled to a bit line (BL) structure 180 through one or more vias 170 and the source feature 142 is electrically coupled to a storage capacitor 200 (depicted in FIGS. 25A and 25B, for example) through one or more vias 190. In this regard, the WL structure 150 (and the channel layer 110) is oriented lengthwise (i.e., elongated) along the Y direction and the BL structure 180 is oriented lengthwise along the X direction. In the depicted embodiment, adjacent memory cells 104 are separated by the dielectric layer 126 along the X direction such that a vertical cell boundary along the Y direction extends through the dielectric layer 126.

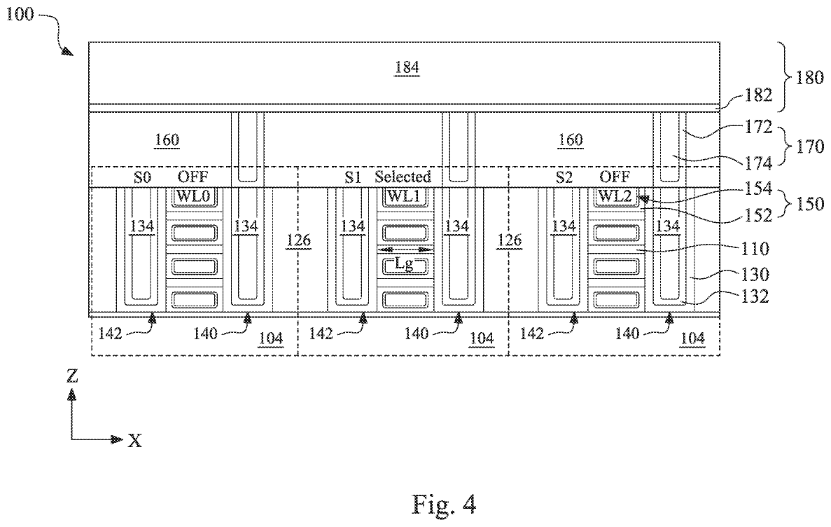

FIG. 4 illustrates an embodiment of the memory device 100 that includes three adjacent memory cells 104 arranged along the X direction, where each memory cell 104 includes a stacked structure of three channel layers 110, similar to the embodiments depicted in FIGS. 1 and 2. The memory cells 104 include the WL structures 150, denoted with WL0, WL1, and WL2, engaged with their respective source features 142 (connected to respective storage capacitors S0, S1, and S2) and corresponding drain features 140. The drain feature 140 of each of the memory cells 104 is coupled to the BL structure 180, which includes a metal layer 184 over a metal layer 182, through the via 170, which includes a metal layer 174 over a metal layer 172. In some examples, the metal layers 172, 174, 182, and 184 may each include a conductive material similar to that of the metal layers 132 and 134 discussed in detail above.

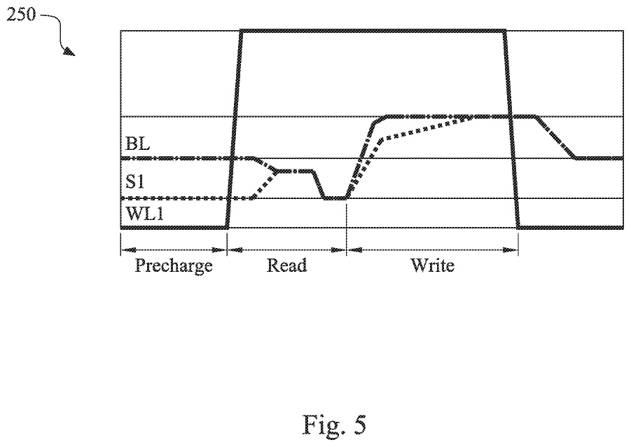

FIG. 5 illustrates an example waveform 250 associated with the operation of the memory device 100 as shown in FIG. 4. In the depicted embodiment, the WL1 of the selected memory cell 104 (center in FIG. 4) is turned on to produce an on-current, or Ion, while the WL0 and WL2 of the unselected memory cells 104 are turned off. The BL structure 180 of the selected memory cell 104 is biased under various conditions to implement “read” and “write” operations. In some embodiments, the increase in the effective channel width W′, where W′ n*W, may increase the Iₒₙ, thereby improving the charging speed of the memory device 100 for high-speed applications. In some embodiments, the stacked channel layers 110 wrapped by the WL structure 150 provides greater gate control within each memory cell 104, leading to lowered leakage, i.e., lower I_{off}, for enhanced device performance.

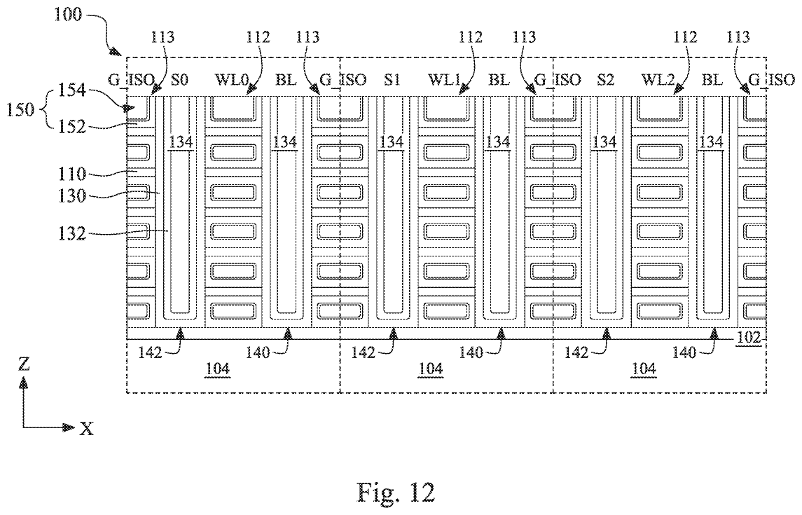

Various embodiments of the memory device 100 are discussed in subsequent FIGS. 6-13, which depict cross-sectional views along line BB′ of the memory cell 104 as shown in FIG. 1. It is noted that various embodiments depicted in FIGS. 6-13 may be modified in accordance with specific design requirements. Furthermore, in each of FIGS. 6-13, three adjacent memory cells 104 are illustrated, where the memory cells 104 include their respective WL structures 150, denoted by WL0, WL1, or WL2, each engaged with the channel layers 110 and interposed between a pair of the drain feature 140 (connected to a common BL structure 180) and the source feature 142 (connected to respective storage capacitors S0, S1, and S2, not depicted).

The memory device 100 depicted in FIGS. 1-4 is a three-layer (or three-sheet) GAA memory device, i.e., three channel layers 110 are interleaved with the WL structure 150 to form each stack 112. The memory device 100 depicted in FIG. 6 is similar to that of FIGS. 1-4 with respect to the number of channel layers 110 in the stack 112. However, different from the depiction of FIGS. 1-4, FIG. 6 shows that the dielectric layer 126 between two adjacent memory cells 104 is replaced by a stack 113, which includes the WL structure 150 interleaved with the channel layers 110, the WL structure 150 configured as an isolation gate (G ISO). In other words, the stacks 112 each including the WL structure 150 (e.g., WL0, WL1, WL2, etc.) are alternatingly arranged with the stacks 113 along the X direction. In this regard, the vertical cell boundary extends through each stack 113 (i.e., each G ISO) rather than through the dielectric layer 126 as depicted in FIGS. 1-4. Advantageously, when a negative voltage is applied to the G ISO, the channel layers 110 in the stack 113 are controlled by the G ISO to prevent leakage of the memory device 100.

The memory device 100 depicted in FIG. 7 is similar to those of FIGS. 1-4 with respect to the number of channel layers 110 in the stack 112. However, different from the depiction of FIGS. 1-4, FIG. 7 shows that each memory cell 104 includes drain features 140 that are shared with an adjacent memory cell 104 such that these drain features 140 are each referred to as a common drain feature (or common drain electrode). In this regard, each memory cell 104 includes a WL structure 150 that couples two adjacent stacks 112 together in a dual-gate structure 114. As shown, each of the WL0, WL1, and WL2 effectively includes a two-sided channel engaged with a pair of the source feature 142 (connected to the respective storage capacitors S0, S1, and S2) and the drain feature 140 (connected to the BL structure 180), where each vertical cell boundary extends through the drain feature 140. Advantageously, the two-sided channel provides greater Iₒₙ (e.g., about doubled) in each memory cell 104 in comparison to the memory cell 104 depicted in FIGS. 1-4 and 6 without enlarging the cell pitch.

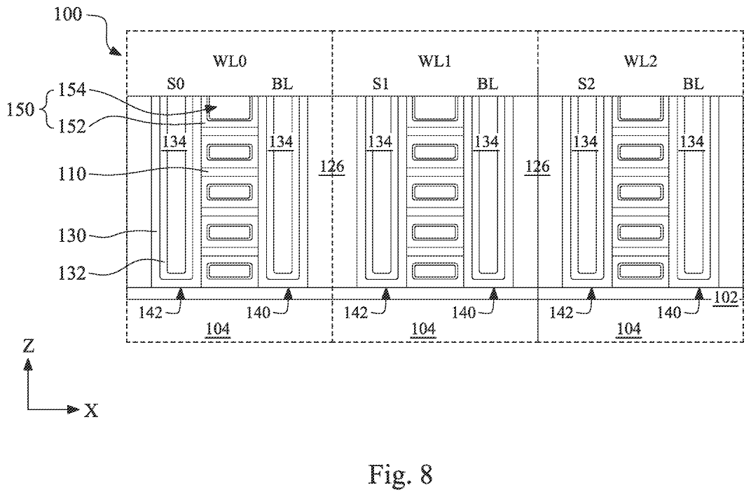

The memory device 100 depicted in each of FIGS. 8-10 is a four-layer GAA memory device, i.e., four channel layers 110 are interleaved with the WL structure 150 to form each stack 112. Accordingly, in comparison with the memory device 100 depicted in FIGS. 1-4, 6, and 7, the memory device 100 of FIGS. 8-10 demonstrate at least the advantage of increased effective channel width W′, which is about four times that of the planar counterpart, for enhanced Iₒₙ performance.

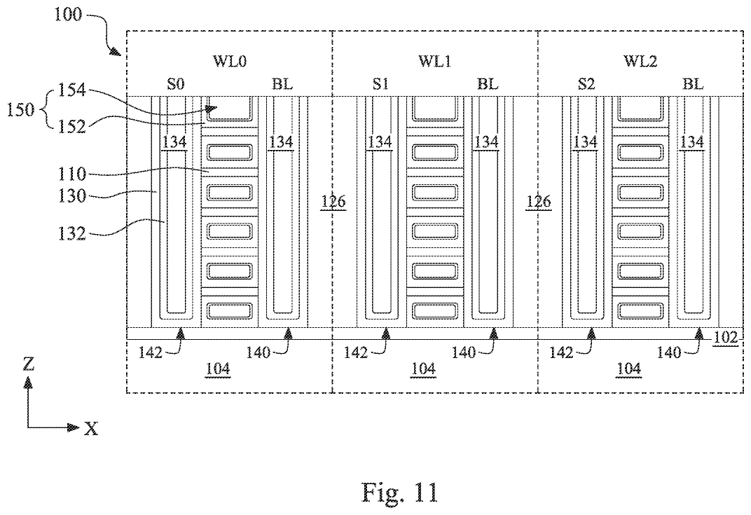

Similarly, the memory device 100 depicted in each of FIGS. 11-13 is a five-layer GAA memory device, i.e., five channel layers 110 are interleaved with the WL structure 150 to form each stack 112. Accordingly, in comparison with the memory device 100 depicted in FIGS. 1-4, 6, and 7, the memory device 100 of FIGS. 11-13 demonstrate at least the advantage of increased War, which is about five times that of the planar counterpart, for enhanced Iₒₙ performance.

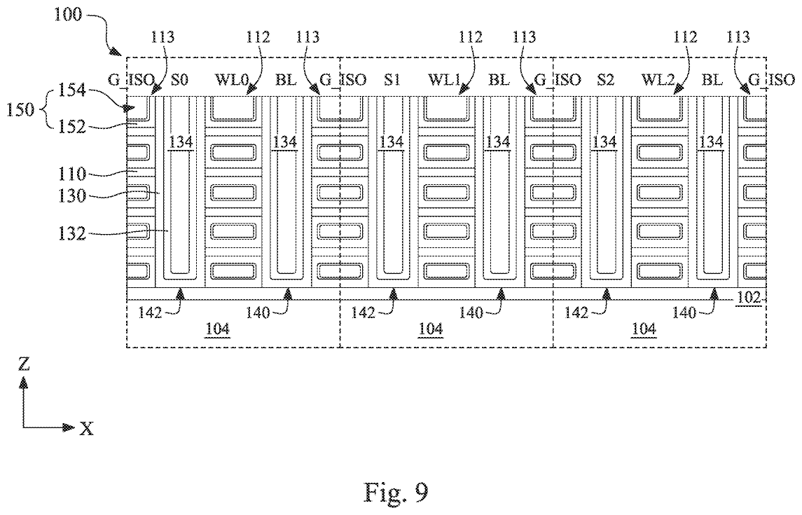

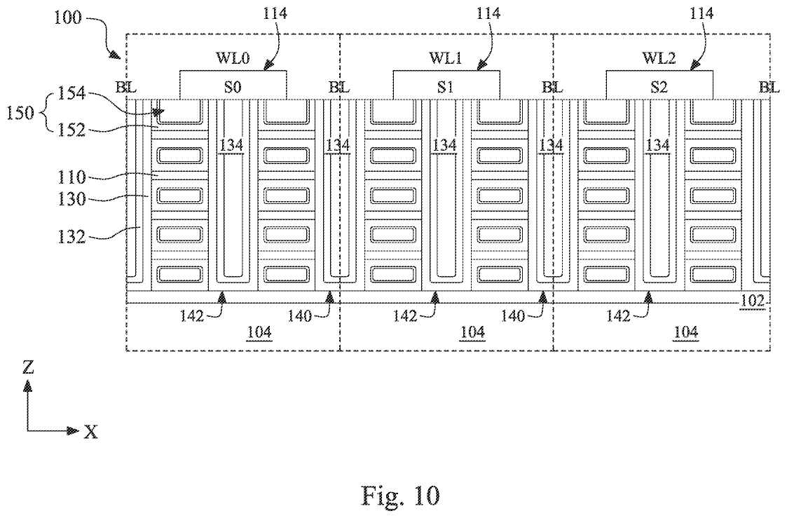

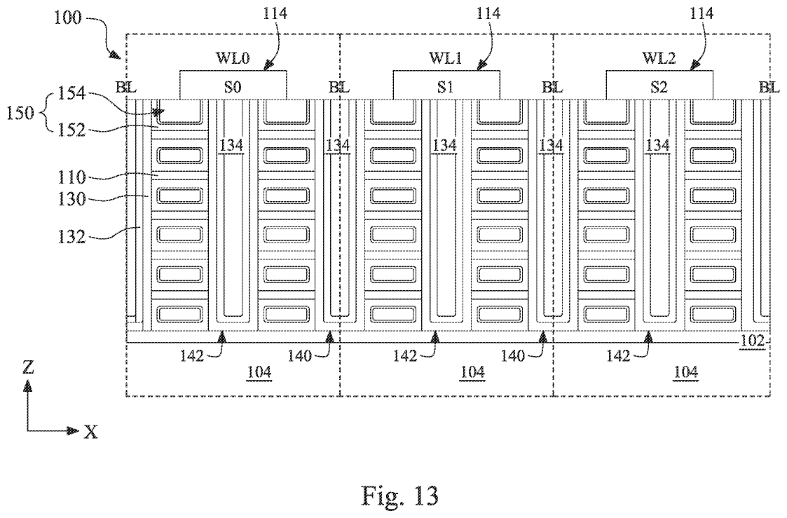

FIGS. 8 and 9 each depict an embodiment that is analogous to that depicted in each of FIGS. 1-4, where adjacent memory cells 104 are separated by the dielectric layer 126. FIGS. 9 and 11 each depict an embodiment that is analogous to that depicted in FIG. 6, where adjacent memory cells 104 are separated by isolation gates G ISO. FIGS. 10 and 13 each depict an embodiment that is analogous to that depicted in each of FIG. 7, where the WL structure of each memory cell 104 is the dual-gate structure 114 configured to provide a two-sided channel for enhanced Iₒₙ performance.

In some examples, during operation of the memory device 100, a voltage V1 applied to bias a selected WL structure 150 exceeds the voltage needed for achieving Iₒₙ of the device, and a voltage V2 applied to bias an unselected WL structure 150 is less than the voltage needed for achieving Iₒₙ, which is less than V1. For embodiments in which the memory device 100 includes isolation gates G ISO (see FIGS. 6, 9, and 12, for example), an additional voltage V3 is applied to bias the G ISO, where V3 is less than V2 and is generally a negative voltage.

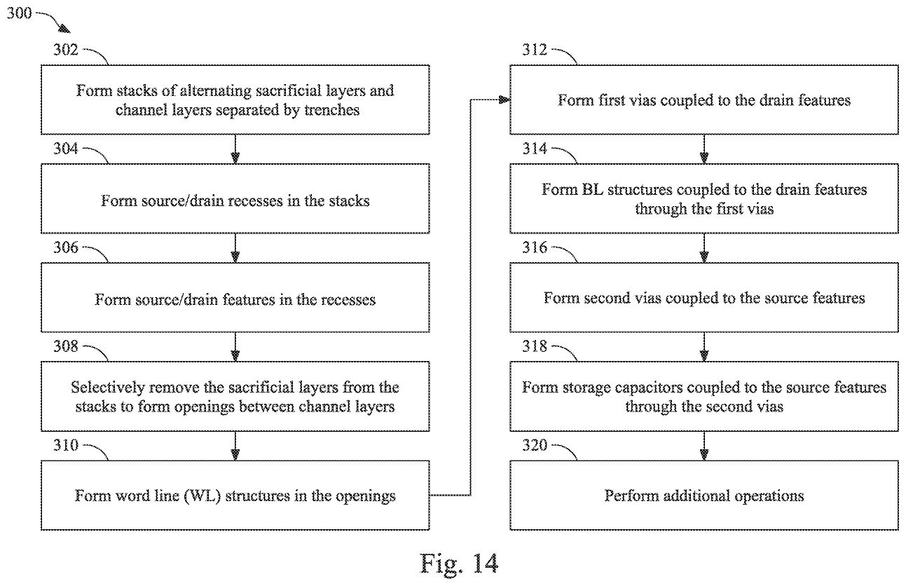

FIG. 14 illustrates a flowchart of a method 300 to form a memory device according to various embodiments of the present disclosure. For example, at least some of the operations (or steps) of the method 300 can be performed to fabricate, make, or otherwise form a memory device (e.g., the memory device 100 of FIG. 1). The method 300 is merely an example, and is not intended to limit the present disclosure. Accordingly, it should be understood that additional operations may be provided before, during, and after the method 300 of FIG. 14, and that some other operations may only be briefly described herein.

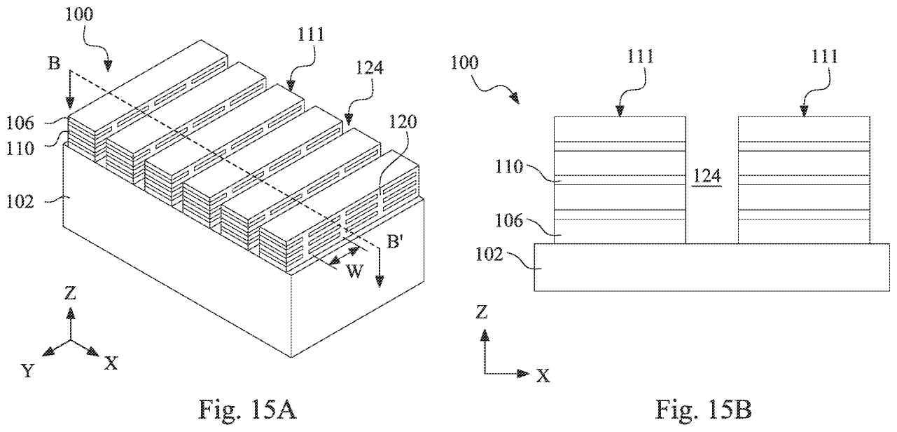

In various embodiments, operations of the method 300 may be associated with perspective views of an example memory device 100 at various fabrication stages as shown in FIGS. 15A-25B, where FIGS. 15A, 16A, 17A, 20A, 21A, 22A, 23A, 24A, and 25A are three-dimensional perspective views of the memory device 100, and FIGS. 15B, 16B, 17B, 18, 19, 20B, 21B, 22B, 23B, 24B, and 25B cross-sectional views along line BB′ of a portion of the memory device 100 as shown in their corresponding perspective views.

Referring to FIGS. 14, 15A, and 15B, the method 300 at operation 302 forms stacks 111 of alternating sacrificial layers 106 and the channel layers 110 over the semiconductor substrate 102, where the stacks 111 are oriented lengthwise along the Y direction and separated by trenches 124 along the X direction.

In the present embodiments, each sacrificial layer 106 includes an insulating or dielectric material, such as silicon oxide (SiO), silicon nitride (SiN), silicon oxynitride (SiON), other suitable dielectric materials, or combinations thereof. Compositions of the channel layer 110 have been discussed in detail above. For example, the channel layer 110 may include one or more metal oxide semiconductor material but may be free, or substantially free, of any silicon-containing semiconductor material. In the present embodiments, the dielectric layer 106 differs from the channel layer 110 in composition to ensure sufficient etching selectivity therebetween. In some examples, the sacrificial layer 106 may include silicon oxide as opposed to a metal oxide of the channel layer 110.

To form the stacks 111, the method 300 first deposits alternating sacrificial layers 106 and the channel layers 110 to form a layered structure (not depicted) using a deposition method, such as chemical vapor deposition (CVD), atomic layer deposition (ALD), physical vapor deposition (PVD), other suitable methods, or combinations thereof. The method 300 then defines the channel width W (also depicted in FIG. 2) in the channel layers 110 by performing a patterning process to form trenches (not depicted) in the layered structure, where the trenches are oriented lengthwise along the X direction and separated from each other by the channel width W along the Y direction.

The trenches may be formed by depositing a masking layer (e.g., a photoresist) over the layered structure, patterning the masking layer using a suitable lithography process (e.g., via photolithography, e-beam lithography, or any other suitable lithographic process) to form a patterned masking layer, and subsequently performing a series of etching processes to transfer the pattern on the patterned masking layer to the layered structure. The etching process may include a plasma etching process, which can have a certain amount of anisotropic characteristic, a wet etching process, a reactive ion etching (RIE) process, other suitable processes, or combinations thereof. In other embodiments, a hard mask may first be patterned using the masking layer and the pattern be subsequently transferred to the layered structure. After patterning the layered structure to form the trenches defining the channel width W, the patterned masking layer is removed by a suitable method, such as plasma ashing or resist stripping.

Subsequently, the method 300 deposits the dielectric layer 120 over the patterned layered structure to fill the trenches such that the dielectric layer 120 is oriented lengthwise along the X direction. The dielectric layer 120 may then be planarized by a process such as a chemical-mechanical polishing/planarizing (CMP), resulting in the dielectric layer 120 being embedded in the stacks 111. In the present embodiments, the dielectric layer 120 is configured to isolate adjacent memory cells 104 along the Y direction. The dielectric layer 120 may be formed by a deposition method, such as CVD, flowable CVD (FCVD), spin-on-coating, other suitable methods, or combinations thereof. In the present embodiments, the dielectric layer 120 and the sacrificial layer 106 differ in composition to ensure sufficient etching selectivity therebetween.

The layered structure with the embedded dielectric layer 120 is then patterned again to form trenches 124 as shown in FIGS. 15A and 15B in a process similar to the patterning process discussed above with respect to forming trenches in the layered structure. The trenches 124 separate the layered structure into the stacks 111 that are oriented lengthwise along the Y direction and spaced from each other along the X direction.

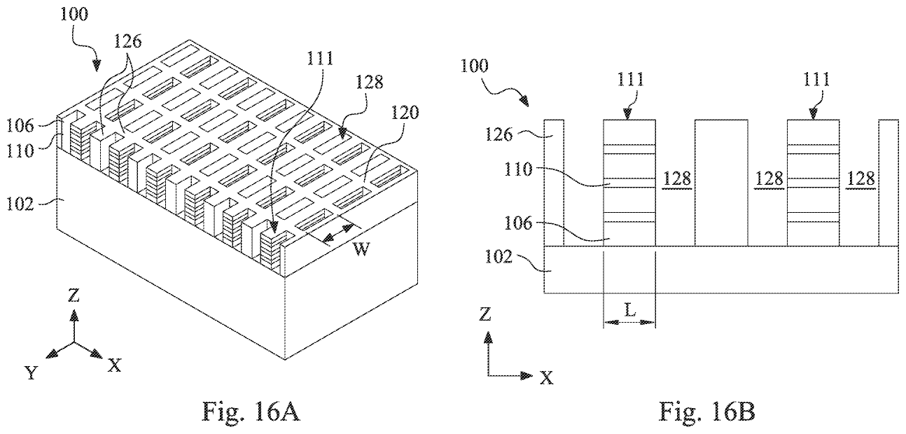

Referring to FIGS. 14, 16A, and 16B, the method 300 at operation 304 forms S/D recesses 128 between the stacks 111.

In some embodiments, as depicted in FIGS. 16A and 16B, forming the S/D recesses 128 includes first filling the trenches 124 with the dielectric layer 126, which is then planarized in a CMP process to expose the topmost sacrificial layer 106 in the stacks 111. The dielectric layer 126 may be similar to the dielectric layer 120 in composition and may be formed by a deposition method, such as CVD, FCVD, spin-on-coating, other suitable methods, or combinations thereof.

Then, the stacks 111 are patterned to form the S/D recesses 128 such that each S/D recess 128 is interposed between a patterned stack 111 and a portion of the dielectric layer 126. In this regard, the patterned stacks 111 define a gate length L along the X direction. The stacks 111 may be patterned in a process similar to that discussed above with respect to forming the trenches in the layered structure.

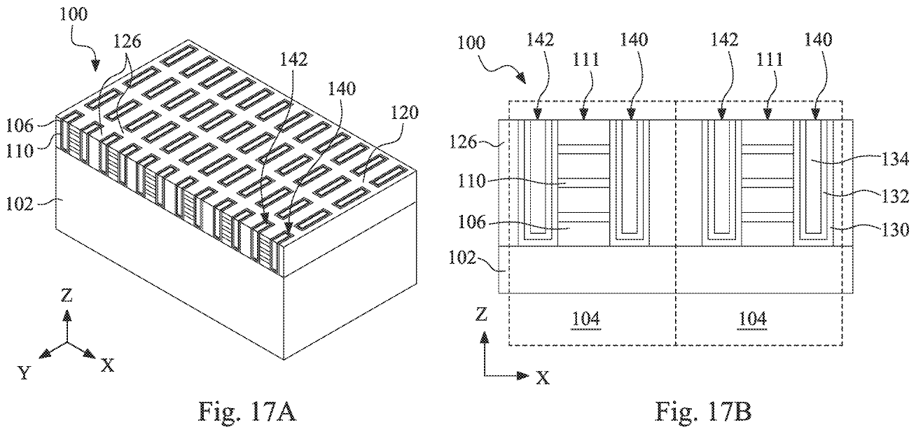

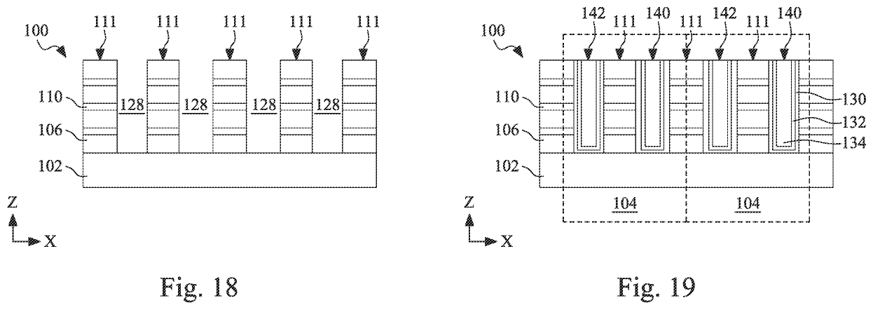

In alternative embodiments, referring to FIG. 18, the S/D recesses 128 are formed by directly patterning the stacks 111 at operation 302 after depositing and planarizing the dielectric layer 120, i.e., the formation of the trenches 124 at operation 302 and the formation of the dielectric layer 126 at operation 304 are omitted. In this regard, each of the S/D recesses 128 is interposed between two patterned stacks 111.

Referring to FIGS. 14, 17A, 17B, and 19, the method 300 at operation 306 forms S/D features, i.e., the drain features 140 and the source features 142, in the S/D recesses 128 such that each patterned stack 111 is interposed between a pair of the drain feature 140 and the source feature 142.

In the present embodiments, forming the S/D features 140/142 includes conformally depositing the contact layer 130 in the S/D recesses 128, conformally depositing the metal layer 132 over the contact layer 130, and depositing the metal layer 134 over the metal layer 132 to fill the S/D recesses 128. Compositions of each of the contact layer 130, the metal layer 132, and the metal layer 134 have been discussed in detail above. The various layers of the S/D features 140/142 may be deposited by any method, such as CVD, ALD, PVD, electroless plating, electroplating, other suitable methods, or combinations thereof. Portions of the contact layer 130, the metal layer 132, and the metal layer 134 formed over a top surface of the patterned stacks 111 may be subsequently removed by one or more CMP processes to expose the topmost sacrificial layer 106, completing the formation of the S/D features 140/142.

In the depicted embodiment of FIG. 17B, the drain feature 140 of one memory cell 104 is separated from the source feature 142 of an adjacent memory cell 104 by the dielectric layer 126. In some embodiments, referring to FIG. 19, two adjacent memory cells 104 adjoin along one of the patterned stacks 111, portions of which are subsequently replaced with the WL structure 150, such that the two adjacent memory cells 104 are separated by a conductive gate structure. The conductive gate structure may be configured as the isolation gate G ISO depicted in FIGS. 6, 9, and 12, or as a part of the dual-gate structure 114 depicted in FIGS. 7, 10, and 13. For purposes of simplicity, the subsequent operations of the method 300 are discussed in reference to the embodiment provided in FIGS. 17A and 17B, though the operations are also applicable to the embodiment depicted in FIG. 19 according to some aspects of the present disclosure.

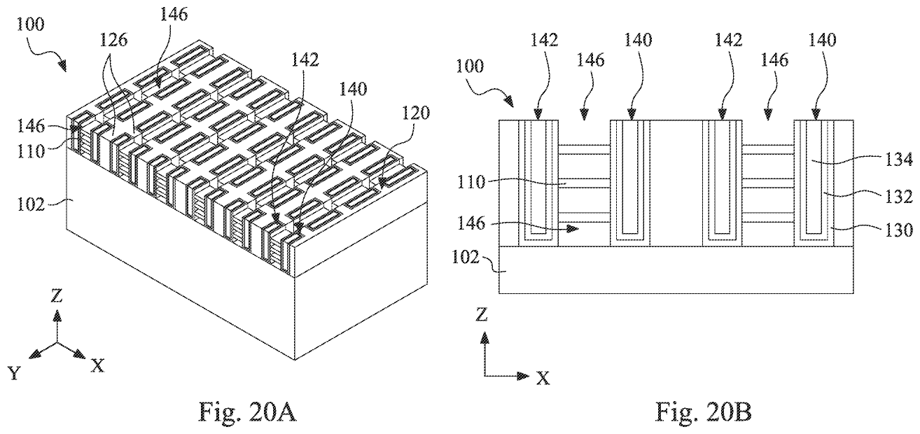

Referring to FIGS. 14, 20A, and 20B, the method 300 at operation 308 selectively removes the sacrificial layers 106 from the patterned stacks 111 to form openings 146 interleaved with the channel layers 110.

The sacrificial layers 106 may be removed by a selective etching process that removes the sacrificial layers 106 without removing, or substantially removing, the channel layers 110 or other surrounding components of the memory device 100. The selective etching process may be implemented as a plasma etching process, a wet etching process, an RIE process, other suitable processes, or combinations thereof.

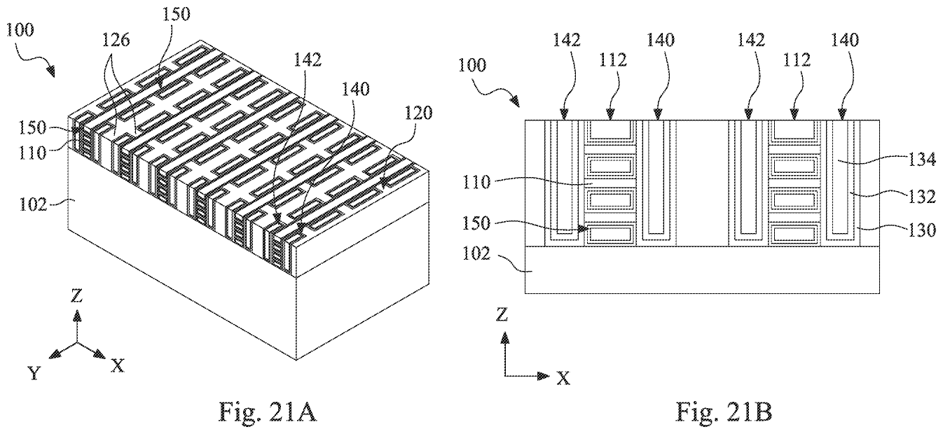

Referring to FIGS. 14, 21A, and 21B, the method 300 at operation 310 forms the WL structure 150 in the openings 146. Accordingly, the WL structure 150, interleaved with (or wrapping around) the channel layers 110, engages with the pair of drain feature 140 and source feature 142 to form the memory cell 104.

In the present embodiments, the WL structure 150 includes at least the dielectric layer 152 and the conductive electrode 154 over the dielectric layer 152, the compositions of which are discussed in detail above. The dielectric layer 152 and the conductive electrode 154 may each be formed by a deposition process, such as CVD, ALD, PVD, electroless plating, electroplating, or combinations thereof. Other material layers, such as an adhesive layer, may be formed over the dielectric layer 152 before forming the conductive electrode 154 or portions thereof. Subsequently, one or more CMP processes may be performed to portions of the dielectric layer 152 and the conductive electrode 154 formed over a top surface of the dielectric layer 126, completing the formation of the WL structure 150 in the openings 146. In the present embodiments, a top surface of the WL structure 150 is formed to be planar with a top surface of the S/D features 140/142.

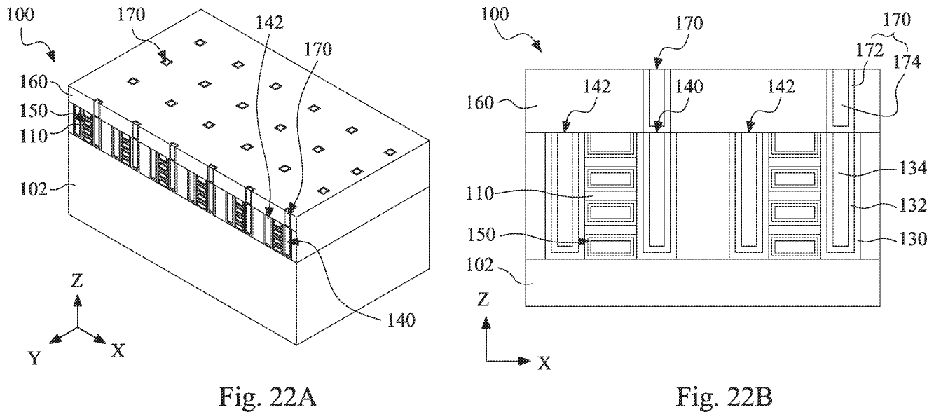

Referring to FIGS. 14, 22A, and 22B, the method 300 at operation 312 forms the via 170, a vertical interconnect structure, configured to electrically couple each drain feature 140 to the BL structure 180. In this regard, the via 170 may be alternatively referred to as a BL VIA.

In the present embodiments, forming the vias 170 includes first forming a dielectric layer 160 over the WL structures 150 of multiple memory cells 104. The dielectric layer 160 may be similar to the dielectric layer 120 in composition and may be formed by a deposition method, such as CVD, FCVD, spin-on-coating, other suitable methods, or combinations thereof. In some examples, an etch-stop layer (ESL; not depicted) may be formed over the WL structures 150 before forming the dielectric layer 160. The ESL includes a dielectric material different from that of the dielectric layers 160, 126, and 120 to ensure sufficient etching selectivity when performing the subsequent etching processes.

Subsequently, the via 170, which may include the metal layer 172 and the metal layer 174 over the metal layer 172, is formed in the dielectric layer 160 by a suitable process, such as a damascene process. The metal layers 172 and 174 may include similar compositions as the metal layer 132 and the metal layer 134 discussed in detail above. For example, the metal layer 172 may include TiN and the metal layer 134 may include W. In some instances, the metal layer 132 may be considered a barrier layer and the metal layer 134 may be considered a metal fill layer.

The damascene process may generally include patterning the dielectric layer 160 to form an opening (not depicted) that extends vertically to expose the underlying drain feature 140, depositing one or more conductive material in the opening, and performing a planarization process, such as a CMP process, to remove any excess conductive material. The conductive material may be deposited by any suitable method, such as CVD, PVD, ALD, electroless plating, electroplating, or combinations thereof.

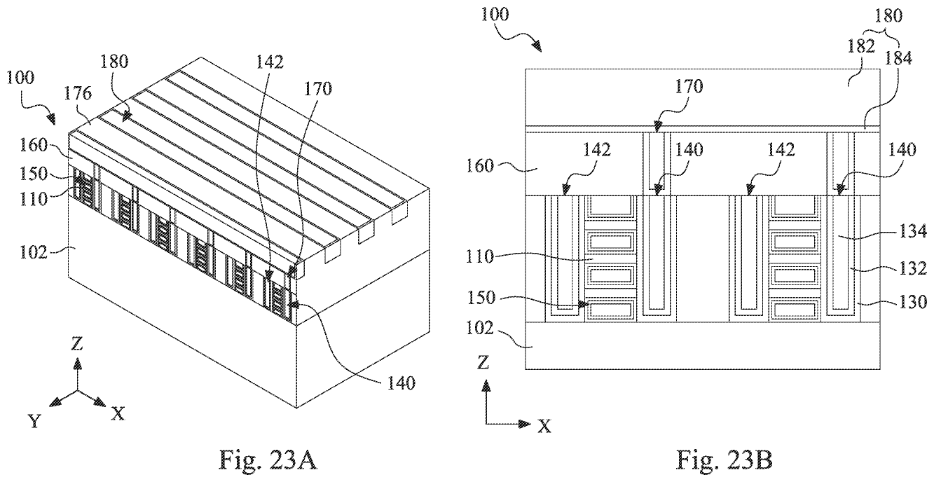

Referring to FIGS. 14, 23A, and 23B, the method 300 at operation 314 forms a BL structure 180, a horizontal interconnect structure, to be electrically coupled to the drain features 140 through the vias 170. In the present embodiments, the BL structures 180, which may be considered global BL structures, extend along the X direction and spaced from each other along the Y direction.

In the present embodiments, forming the BL structures 180 includes first forming a dielectric layer 176 over the dielectric layer 169. The dielectric layer 176 may be similar to the dielectric layer 120 in composition and may be formed by a deposition method, such as CVD, FCVD, spin-on-coating, other suitable methods, or combinations thereof. In some examples, an ESL may be formed over the dielectric layer 160 before forming the dielectric layer 160. The ESL includes a dielectric material different from that of the dielectric layers 176 and 160 to ensure sufficient etching selectivity when performing the subsequent etching processes.

The BL structures 180 may each include the metal layer 184 over the metal layer 182. The metal layers 182 and 184 may include similar compositions as the metal layer 132 and the metal layer 134 discussed in detail above. For example, the metal layer 182 may include TiN and the metal layer 184 may include W. In some instances, the metal layer 182 may be considered a barrier layer and the metal layer 184 may be considered a metal fill layer. The BL structures 180 are formed in a similar manner as the vias 170, such as by a damascene process discussed in detail above, and subsequently planarized using one or more CMP processes. In some examples, the BL structures 180 and the vias 170 may be formed together by a dual-damascene process.

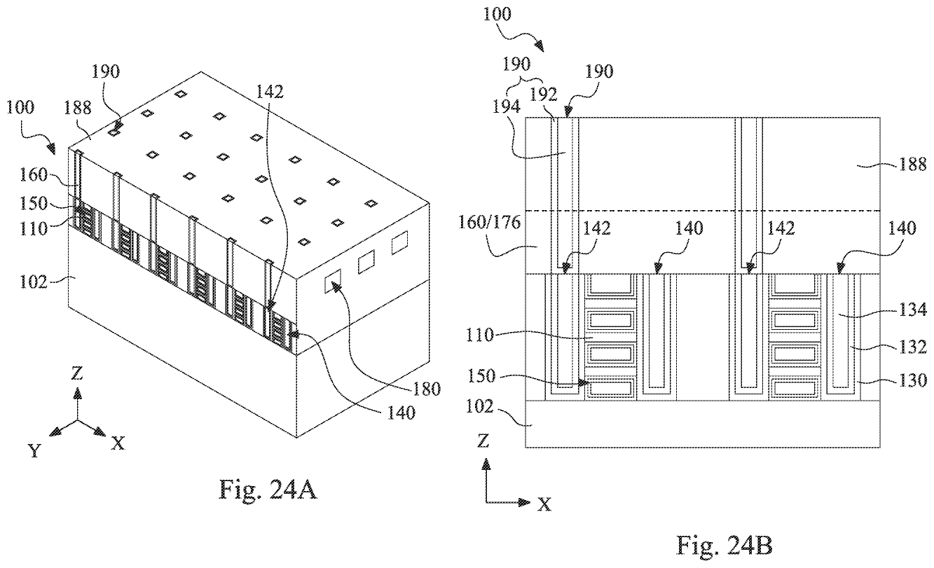

Referring to FIGS. 14, 24A, and 24B, the method 300 at operation 316 forms the via 190 to electrically couple each source feature 142 to a subsequently-formed storage capacitor 200. In this regard, the via 190 may be alternatively referred to as a CVIA.

In the present embodiments, the via 190 is similar to the via 170 in terms of structure and method of formation. For example, the via 190 may include a metal layer 192 and a metal layer 194 over the metal layer 192, which may be similar in composition as the metal layers 134 and 132 as discussed above. Furthermore, the via 190 may be formed by a process similar to that discussed above with respect to the via 170. For example, a dielectric layer 188 is formed over the dielectric layer 176 by a suitable deposition method as discussed above, and a damascene process, for example, may be performed to form the vias 190 in the dielectric layers 188, 176, and 160. Subsequently, one or more CMP processes may be performed to expose a top surface of the dielectric layer 188.

Referring to FIGS. 14, 25A, and 25B, the method 300 at operation 318 forms the storage capacitors 200 each electrically coupled to the source feature 142 through the via 190. In this regard, the via 190 may be alternatively referred to as the CVIA.

In some embodiments, forming the storage capacitor 200 includes first forming a dielectric structure 192 over the dielectric layer 188 (and the vias 190). The dielectric structure 192 may be a layered structure including a dielectric layer 194, a dielectric layer 196 over the dielectric layer 194, and a dielectric layer 198 over the dielectric layer 196, where the dielectric layers 194, 196, and 198 may differ in composition. The dielectric layers 194, 196, and 198 may each include a suitable dielectric material, such as silicon oxide (SiO), silicon nitride (SiN), silicon oxynitride (SiON), aluminum oxide (Al₂O₃), dielectric material(s) with low dielectric constant (low-k), including SiCOH, SiOCN, and/or SiOC, other suitable materials, or combinations thereof. The dielectric structure 192 may include less, more, or different layers as those provided herein. The dielectric layers 194, 196, and 198 may each be formed by a deposition method, such as CVD, FCVD, ALD, PVD, spin-on-coating, other suitable methods, or combinations thereof.

Subsequently, openings (not depicted) are formed in the dielectric structure 192 to expose the vias 190, where each opening corresponds to a storage capacitor 200. Each storage capacitor 200 may include a bottom plate 202, a capacitor dielectric layer 204 over the bottom plate 202, and a top plate 206 over the capacitor dielectric layer 204. Each of the bottom plate 202 and the top place 204 may include a conductive material, such as TaN, TiN, W, Al, Ru, Co, Cu, Mo, Nb, other suitable conductive materials, or combinations thereof, and the capacitor dielectric layer 204 may include a suitable dielectric material, such as dielectric material(s) with high dielectric constant (high-k), including hafnium oxide (HfO₂), aluminum oxide (Al₂O₃), tantalum oxide silicon (Ta₂O₅), zirconium oxide (ZrO₂), other suitable dielectric materials, or combinations thereof. Each layer of the storage capacitor 200 may be formed by a suitable method, such as CVD, ALD, PVD, electroless plating, electroplating, or combinations thereof.

Furthermore, the method 300 at operation 320 may perform additional operations. For example, additional interconnect features, such as vias and conductive lines, may be formed over the memory device 100 according to various design requirements.

The present disclosure provides various embodiments of a BEOL memory device having a three-dimensional nanosheet-based channel structure. In many embodiments, the BEOL memory device includes a stack of channel layers (i.e., nanosheets) engaged with a word line structure, which functions as a gate of the device, and interposing between a source feature and a drain feature. The channel layer includes a conductive oxide material. The word line structure may further include a metal fill layer disposed over a dielectric layer. In some embodiments, the device is disposed over an FEOL device formed along a surface of an underlying substrate. In some embodiments, the drain feature is further connected to a bit line structure through a first via and the source feature is further connected to a storage capacitor through a second via. By forming the word line structure to wrap around multiple channel layers in a stack, gate control of the memory device is improved and an effective channel width of the memory device is increased in accordance to the number of channel layers included in the stack and the gate control, leading to enhanced the on-current of the memory device for high speed applications.

In one aspect of the present disclosure, a memory device is disclosed. The memory device includes a semiconductor substrate. The memory device includes a stack of channel layers over the semiconductor substrate, each channel layer including an oxide material. The memory device includes a word line structure interleaved with the stack of channel layers. The memory device includes a source feature and a drain feature on both sides of the stack of channel layers.

In another aspect of the present disclosure, a memory device is disclosed. The memory device includes a semiconductor substrate and a memory cell over the semiconductor substrate. The memory cell includes a stack of channel layers, each channel layer including a metal oxide. The memory cell includes a word line structure wrapping around each channel layer. The memory cell includes a source metal electrode and a drain metal electrode on both sides of the stack of channel layers.

In yet another aspect of the present disclosure, a method for fabricating a memory devices is disclosed. The method includes forming a stack of alternating sacrificial layers and channel layers over a substrate, the stack being oriented lengthwise along a first direction, where each channel layer includes a first metal oxide material. The method includes patterning the stack to form recesses in the stack, the recesses being oriented lengthwise along the first direction. The method includes forming a source feature and a drain feature in the recesses. The method includes selectively removing the sacrificial layers in the patterned stack to form openings between the channel layers. The method includes forming a word line structure in the openings, wherein the word line structure wraps around each channel layer in the stack, the word line structure being oriented lengthwise along the first direction.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a semiconductor substrate;
a stack of channel layers over the semiconductor substrate, each channel layer including a conductive oxide material;
a word line structure interleaved with the stack of channel layers; and
a source feature and a drain feature on both sides of the stack of channel layers.

2. The memory device of claim 1, wherein each channel layer is an N-type channel layer, and wherein the conductive oxide material includes indium gallium zinc oxide (IGZO), zinc oxide (ZnO), indium oxide (In₂O₃), tin oxide (SnO₂), or combinations thereof.

3. The memory device of claim 1, wherein each channel layer is a P-type channel layer, and wherein the conductive oxide material includes nickel oxide (NiO), copper oxide (Cu₂O), copper aluminum oxide (CuAlO₂), copper gallium oxide (CuGaO₂), copper indium oxide (CuInO₂), strontium copper oxide (SrCu₂O₂), tin oxide (SnO), or combinations thereof.

4. The memory device of claim 1, wherein the conductive oxide material is a first conductive oxide material, and wherein the source feature and the drain feature each include a metal layer over a contact layer, the contact layer including a second conductive oxide material.

5. The memory device of claim 4, wherein the first conductive oxide material is the same as the second conductive oxide material.

6. The memory device of claim 4, wherein the first conductive oxide material includes a first oxygen concentration and the second conductive oxide material includes a second oxygen concentration, and wherein the second oxygen concentration is less than the first oxygen concentration.

7. The memory device of claim 1, further comprising a dielectric layer disposed along a sidewall of each of the source feature and the drain feature.

8. A memory device, comprising:
a semiconductor substrate; and
a memory cell over the semiconductor substrate, including:
a stack of channel layers, each channel layer including a metal oxide;
a word line structure wrapping around each channel layer; and
a source metal electrode and a drain metal electrode on both sides of the stack of channel layers.

9. The memory device of claim 8, wherein the memory cell is a first memory cell, the memory device further comprising a second memory cell adjacent the first memory cell, and wherein the first memory cell and the second memory cell are separated by a dielectric layer.

10. The memory device of claim 8, wherein the memory cell is a first memory cell, the memory device further comprising a second memory cell adjacent the first memory cell, and wherein the drain metal electrode of the first memory cell is a common drain electrode shared between the first memory cell and the second memory cell.

11. The memory device of claim 8, wherein the memory cell is a first memory cell and the word line structure is a first word line structure, and wherein the memory cell further includes a second word line structure disposed at a cell boundary.

12. The memory device of claim 8, further comprising a bit line structure electrically connected to the drain metal electrode through a first via and a storage capacitor electrically connected to the source metal electrode through a second via.

13. The memory device of claim 8, wherein the metal oxide is a first metal oxide, and wherein the source metal electrode and the drain metal electrode each include a contact layer having a second metal oxide.

14. The memory device of claim 8, wherein the metal oxide is a first metal oxide, and wherein the word line structure includes a conductive electrode over a dielectric layer having a second metal oxide, the first metal oxide and the second metal oxide having different compositions.

15. A method of fabricating a memory cell, comprising:
forming a stack of alternating sacrificial layers and channel layers over a substrate, the stack being oriented lengthwise along a first direction, wherein each channel layer includes a metal oxide material;
patterning the stack to form recesses in the stack, the recesses being oriented lengthwise along the first direction;
forming a source feature and a drain feature in the recesses;
selectively removing the sacrificial layers in the patterned stack to form openings between the channel layers; and
forming a word line structure in the openings, wherein the word line structure wraps around each channel layer in the stack, the word line structure being oriented lengthwise along the first direction.

16. The method of claim 15, wherein the metal oxide material is a first metal oxide material, and wherein the forming of the source feature and the drain feature includes:
depositing a contact layer in the recesses, wherein the contact layer includes a second metal oxide material that differs from the first metal oxide material in oxygen concentration;
forming a first metal layer over the contact layer; and
forming a second metal layer over the first metal layer to fill the recesses.

17. The method of claim 16, wherein the first metal oxide material and the second metal oxide material each include indium gallium zinc oxide (IGZO), zinc oxide (ZnO), indium oxide (In₂O₃), tin oxide (SnO₂), nickel oxide (NiO), copper oxide (Cu₂O), copper aluminum oxide (CuAlO₂), copper gallium oxide (CuGaO₂), copper indium oxide (CuInO₂), strontium copper oxide (SrCu₂O₂), tin oxide (SnO), or combinations thereof.

18. The method of claim 15, wherein the forming of the stack includes forming a dielectric layer embedded in the stack, the dielectric layer extending vertically through the stack and being oriented lengthwise along a second direction perpendicular to the first direction, and wherein a length of a portion of the stack adjacent the dielectric layer defines a channel width of the memory cell.

19. The method of claim 15, further comprising, before the patterning of the stack, forming a dielectric layer over a sidewall of the stack along the first direction such that each of the recesses is formed to interpose between the patterned stack and the dielectric layer.

20. The method of claim 15, further comprising:
forming a first via to directly contact the drain feature;
forming a bit line structure to directly contact the first via such that the bit line structure is electrically coupled to the drain feature, the bit line structure being oriented lengthwise along a second direction perpendicular to the first direction;
forming a second via to directly contact the source feature; and
forming a storage capacitor to directly contact the second via such that the storage capacitor is electrically coupled to the source feature.
